(19) United States
(12) Patent Application Publication
(10) Pub. No.: US 2011/0075861 A1
(43) Pub. Date: Mar. 31, 2011

(54) Method and Apparatus for Controlling Audio Input Amplitude

(75) Inventors: Guoqi Wu, Shenzhen (CN); Jianrui Ren, Shenzhen (CN); Weiqing Zheng, Shenzhen (CN)

(73) Assignee: Zoran Corporation, Sunnyvale, CA (US)

(21) Appl. No.: 12/299,238

(22) PCT Filed: Jun. 12, 2008
(86) PCT No.: PCT/CN2008/001138

§ 371 Date: Oct. 31, 2008

(51) Int. Cl. H03G 3/20

(52) U.S. Cl. 381/107

(57) ABSTRACT

Amplitude of an audio input may be dynamically controlled within a predefined range of an analog-to-digital converter (ADC) threshold voltage. In one embodiment, an analog audio signal having a first voltage amplitude may be received by an amplifier. The analog audio signal may be amplified based on a gain control signal and converted to digital audio data by the ADC. The difference of the first voltage amplitude and the threshold voltage of the ADC may be determined and a gain control signal can be adjusted for the amplifier based, at least in part, on the difference in the first voltage amplitude and the threshold voltage of the ADC. The received analog audio signal characterized by a second voltage amplitude can be output.

### FIELD OF THE INVENTION

The present invention relates generally to audio processing and more particularly to a system for controlling input signal amplitude.

### BACKGROUND

Conventional audio systems employing fixed gain input devices, such as microphones, can suffer a decrease in performance when input signals exceed a threshold of one or more audio system components. Such decreased performance may include signal distortion and/or clipping of input signals. Similarly, processing of audio input signals below a certain threshold can result in a decrease in performance of the above-identified conventional systems including significant decreases in signal-to-noise ratio.

One conventional approach to improving audio system performance may include upgrading system components to increase operational range. For example, in the audio industry increasing the available conversion bits of an analog-to-digital converter (ADC) may result in improved signal response. However, such modifications can result in increased cost and limit operation flexibility. Further, the addition of other hardware components which may expand operation performance may additionally result in increased cost and device requirements.

Thus, there is an unsatisfied need for a system and method for addressing input signal amplitude control.

### BRIEF SUMMARY OF THE INVENTION

Disclosed and claimed herein are a system and method for dynamically controlling amplitude of an audio input within a predefined range of an analog-to-digital converter (ADC) threshold voltage. In one embodiment, a process is provided to include receiving an analog audio signal having a first voltage amplitude by an amplifier, amplifying the analog audio signal based on a gain control signal, converting the analog audio signal to digital audio data, determining a difference in the first voltage amplitude and the threshold voltage of the ADC, adjusting the gain control signal for the amplifier based, at least in part, on the difference in the first voltage amplitude and the amplitude threshold of the ADC, and outputting the received analog audio signal characterized by a second voltage amplitude.

Other aspects, features, and techniques of the invention will be apparent to one skilled in the relevant art in view of the following detailed description of the invention.

### BRIEF DESCRIPTION OF THE DRAWINGS

FIG. 1 depicts a simplified system diagram of a gain control system according to one embodiment of the invention;

FIG. 2 depicts a process for controlling amplitude of an audio input according to one or more embodiments of the invention; and

FIG. 3 depicts a process for adjusting gain according to one or more embodiments of the invention.

### DETAILED DESCRIPTION OF EXEMPLARY EMBODIMENTS

One aspect of the present invention is directed to audio processing, and more particularly to a system for controlling input signal amplitude to promote signal to noise ratio. As will be described in more detail below, an audio input signal may be amplified dynamically to adjust amplitude of the audio input signal. In one embodiment, a digital signal processor may be configured to output a gain control signal to an audio amplifier. The amplitude of the audio input signal may be amplified by a gain factor to improve signal-to-noise ratio (SNR) of the received audio input signal.

In one embodiment, a process may be provided for controlling amplitude of an analog input signal. The input signal amplitude may be controlled within a predefined level of an analog-to-digital converter (ADC) threshold. The process may include converting a received analog audio signal to digital audio data by the ADC. The amplitude of the analog audio signal may be adjusted, as will be described below in more detail. The process may also include adjusting a gain control signal by a digital signal processor (DSP).

As used herein, the terms “a” or “an” shall mean one or more than one. The term “plurality” shall mean two or more than two. The term “another” is defined as a second or more. The terms “including” and/or “having” are open ended (e.g., comprising). The term “or” as used herein is to be interpreted as inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive. Reference throughout this document to “one embodiment”, “certain embodiments”, “an embodiment” or similar term means that a particular feature, structure, or characteristic described in connection with the embodiment is included in at least one embodiment of the present invention. Thus, the appearances of such phrases in various places throughout this specification are not necessarily all referring to the same embodiment. Furthermore, the particular features, structures, or characteristics may be combined in any suitable manner on one or more embodiments without limitation.

In accordance with the practices of persons skilled in the art of computer programming, the invention is described below with reference to operations that are performed by a computer system or a like electronic system. Such operations are sometimes referred to as being computer-executed. It will be appreciated that operations that are symbolically represented include the manipulation by a processor, such as a central processing unit, of electrical signals representing data bits and the maintenance of data bits at memory locations, such as in system memory, as well as other processing of signals. The memory locations where data bits are maintained are physical locations that have particular electrical, magnetic, optical, or organic properties corresponding to the data bits.

When implemented in software, the elements of the invention are essentially the code segments to perform the necessary tasks. The program or code segments can be stored in a processor readable medium. The “processor readable medium” may include any medium that can store or transfer information. Examples of the processor readable medium include an electronic circuit, a semiconductor memory device, a ROM, a flash memory or other non-volatile memory, a floppy diskette, a CD-ROM, an optical disk, a hard disk, a fiber optic medium, etc. The code segments may be downloaded via computer networks such as the Internet, Intranet, etc.

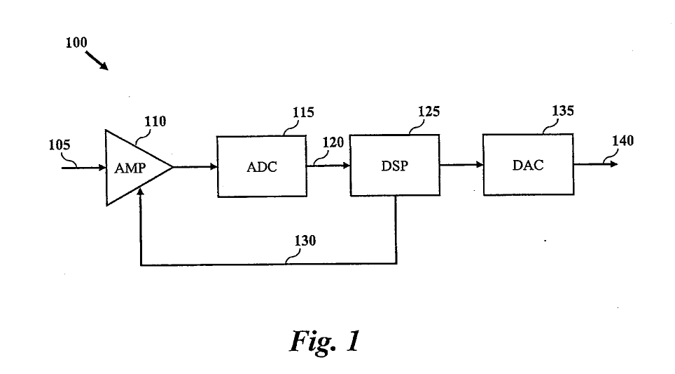

Referring now to the drawings, FIG. 1 illustrates a simplified block diagram of a system according to one or more embodiments of the invention. As shown in FIG. 1, system 100 includes an amplifier 110, ADC 115, DSP 125, and digital-to-analog converter (DAC) 135. System 100 may be configured to dynamically control amplitude of an analog audio input based on the amplitude of the analog audio input and/or a voltage amplitude threshold of ADC 115. In certain embodiments, system 100 may relate to an audio system, public address system, microphone amplification system, electronic media player, digital video disc audio processor and audio processing system in general. As such, it may be appreciated that analog audio input, shown as 105, received by system 100 may relate to one or more analog audio signals. In certain embodiments, system 100 may be configured to receive a digital data signal (not shown). Analog audio input 105 may be received from an input terminal of an electronic device. According to another embodiment, analog audio input 105 maybe received wirelessly.

According to another embodiment, amplifier 110 may relate to a voltage controlled amplifier. As such, the gain of amplifier 110 may be controlled by a gain control signal received over data link 130. Analog audio input 105, such as an analog audio signal, received by amplifier 110 may be amplified based on the gain control signal received over data link 130. In one embodiment, the gain control signal may be provided by DSP 125.

ADC 115 may be configured to convert an analog audio signal received from amplifier 110 to digital data. ADC 115 may provide one or more digital output signals, shown as 120, related to at least one of a binary, Gray code, two's complement binary and digital coding scheme in general. It may also be appreciated that ADC 115 may have a resolution of 8 to 24 bits. It may also be appreciated ADC 115 may have a voltage threshold for audio input signals. In one exemplary embodiment, ADC 115 may have an operable voltage range of 0 to 12 volts. However, it may also be appreciated that ADC's having other voltage ranges may be employed by system 100. In a further embodiment, quantization error of ADC 115 may be below 0.000715 mv.

DSP 125 may be configured to detect amplitude of analog audio signal based on one or more signals received from ADC 115. In one embodiment, DSP 125 can provide one or more control signals to amplifier 110 based on a detected amplitude of analog audio input 105. DSP 125 may be configured to provide a gain control signal over data link 130 to amplifier 110 for at least one of increasing, decreasing and applying a gain of one to analog audio input 105. According to another embodiment, a gain control signal provided by DSP 125 may be based on an voltage threshold of ADC 115. In that fashion, analog audio input 105 may be amplified to improve SNR and/or reduce distortion. DSP 125 may be configured to provide digital audio data to DAC 135. Audio data received by system 100 may be output as an analog audio signal, shown as output 140 in FIG. 1.

According to another embodiment, DSP 125 may be configured to detect distortion in analog audio input 105. In one embodiment, DSP 125 may be configured to provide one or more control signals to amplifier 110 to reduce detected distortion using data link 130. According to another embodiment, DSP 125 may be configured for interpolation and/or extrapolation of known samples to repair clipping distortion, for example. It may also be appreciated the DSP 125 may be configured to process received audio data. For example, DSP 125 may be configured for one or more of bit-stream decoding and audio effect processing (e.g., echo, chorus, flange, equalizer, etc.) Similarly, DSP 125 can store output of ADC 115 using memory (not shown FIG. 1). It should be appreciated that DSP 125 may relate to any type of processor such as a microprocessor, field programmable gate array (FPGA) and/or application specific integrated circuit (ASIC).

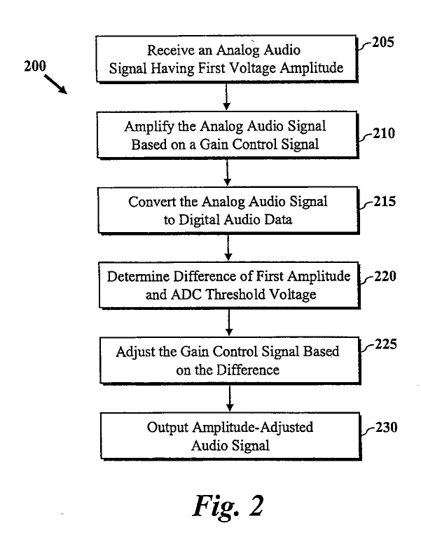

Referring now to FIG. 2, a simplified diagram is shown of a process which may be performed by the system (e.g., system 100) of FIG. 1 according to one or more embodiments of the invention. As shown in FIG. 2, process 200 may be initiated by receiving an analog audio signal having a first voltage amplitude by an amplifier (e.g., amplifier 110) at block 205. As used herein, the analog audio signal may relate to at least one of voice, music, ambient noise and sound in general. The analog audio signal (e.g., analog audio input 105) can be amplified by an amplifier (e.g., amplifier 110) based on a gain control signal at block 210. Process 200 may continue with converting the analog audio signal to digital audio data by an ADC (e.g., ADC 115) at block 215. At block 220, a difference in the first amplitude and a threshold voltage of the ADC may be determined by the DSP (e.g., DSP 125). The DSP may also be configured to determine the first voltage amplitude of the analog audio signal. In certain embodiments, an amplitude of received analog audio signal may be above or below an ADC threshold.

According to another embodiment, a gain control signal of the amplifier may be adjusted based, at least in part, on the difference (determined at block 215) in the first amplitude and the threshold voltage of the ADC at block 225. In certain embodiments, the gain control signal may be adjusted such that an amplifier (e.g., amplifier 110) increases or decreases an analog audio signal amplitude to a second voltage amplitude that is within a range of an ADC threshold voltage. For example, an analog audio signal may be adjusted within ±1 volt of ADC threshold voltage. The received analog audio signal may be output as an analog signal characterized by the second voltage amplitude at block 230. It may also be appreciated that a gain control signal of the amplifier may be adjusted at block 225 to increase the SNR of the audio signal.

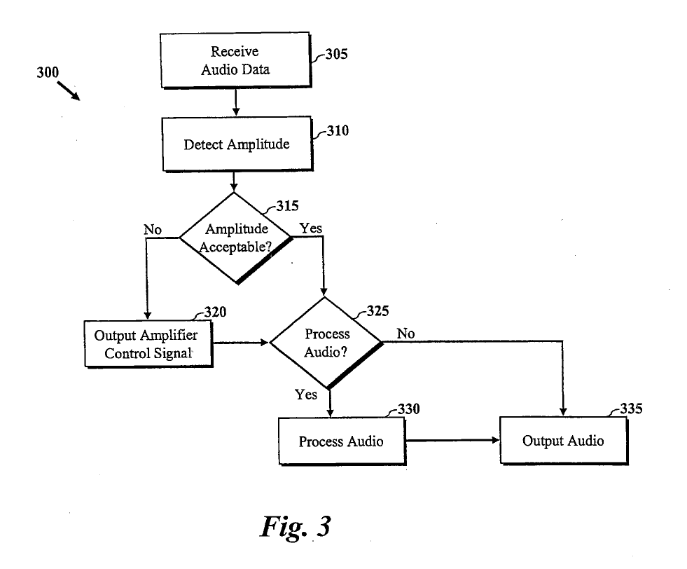

Referring now to FIG. 3, a process is shown for controlling amplitude of an audio input signal by a DSP (e.g., DSP 125), according to one or more embodiments of the invention. Process 300 may be initiated at block 305 by receiving audio data. The DSP can determine an amplitude of the received audio data at block 310. Process 300 may include determining if the received audio data conforms to an acceptable amplitude in block 315. When received audio data does not conform within a predefined amplitude (“No” path out of decision block 315), the DSP may provide a control signal to an amplifier (e.g., amplifier 110) to modify input audio amplitude at block 320. In particular, the audio amplitude may be increased and/or decreased by the DSP at block 320. When the received data relates to an acceptable amplitude level (“Yes” path out of decision block 315), or after adjustment at block 320, the DSP may determine block 325 if the received audio data requires processing. In certain embodiments, the DSP may be configured to process received audio for reduction of noise, adding effects, filtering, etc. When the received audio data requires processing as determined by the DSP (“Yes” path out of decision block 325), the audio data may be processed DSP may at block 330. Processing at block 330 may include one or more of detecting a distortion level of the audio data and adjusting the gain control signal for the amplifier based on the detected distortion level. When received audio data does not require processing (“No” path out of decision block 325) audio data may be output at block 335.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art. Trademarks and copyrights referred to herein are the property of their respective owners.

1-20. (canceled)

21. A method for dynamically controlling amplitude of an audio input within a predefined range of an analog-to-digital converter (ADC) threshold voltage, the method comprising the acts of:
receiving an analog audio signal having a first voltage amplitude by an amplifier;
amplifying the analog audio signal based on a gain control signal;
converting the analog audio signal to digital audio data;
determining a difference in the first voltage amplitude and the threshold voltage of the ADC;
adjusting the gain control signal for the amplifier based, at least in part, on the difference in the first voltage amplitude and the amplitude threshold of the ADC; and
outputting the received analog audio signal characterized by a second voltage amplitude.

22. The method of claim 21, wherein adjusting the gain control signal comprises outputting a gain control signal to the amplifier such that the received analog audio signal is amplified to the second voltage amplitude, the second voltage amplitude below the threshold voltage of the ADC.

23. The method of claim 22, wherein the second voltage amplitude relates to an audio signal amplitude having a maximized signal-to-noise ratio.

24. The method of claim 21, wherein outputting the received analog signal characterized by a second voltage amplitude is performed in real time.

25. The method of claim 21, wherein the second voltage amplitude relates to one of a reduced and increased amplitude in relation to the first voltage amplitude.

26. The method of claim 21, wherein outputting the received analog audio signal characterized by a second voltage amplitude comprises converting the digital audio data to an analog audio signal.

27. The method of claim 21, further comprising detecting the threshold voltage of the ADC related to at least one of a distortion threshold and clipping threshold.

28. The method of claim 21, further comprising determining the first voltage amplitude of the analog audio signal based on the received digital audio data by a digital signal processor.

29. The method of claim 21, further comprising:
detecting a distortion level of the received analog audio signal; and
adjusting the gain control signal for the amplifier based, at least in part, on the detected distortion level.

30. The method of claim 21, further comprising amplifying the received analog audio signal by a gain of one based on the gain control signal received by the amplifier.

31. A system comprising:
an amplifier configured to receive an analog audio signal having a first voltage amplitude and amplify the analog audio signal based on a gain control signal;
an analog-to-digital converter (ADC) configured to convert the analog audio signal to digital audio data; and
a digital signal processor (DSP) coupled to the ADC and amplifier, wherein the DSP is configured to:
determine a difference in the first voltage amplitude and the threshold voltage of the ADC; and
adjust the gain control signal for the amplifier based, at least in part, on the difference in the first voltage amplitude and the amplitude threshold of the ADC.

32. The system of claim 31, wherein the DSP is to adjust the gain control signal by outputting the gain control signal to the amplifier such that the received analog audio signal is amplified to the second voltage amplitude, the second voltage amplitude below the threshold voltage of the ADC.

33. The second voltage amplitude relates to an audio signal amplitude having a maximized signal-to-noise ratio.

34. The system of claim 31, wherein the amplifier is configured to output the received analog signal characterized by a second voltage amplitude in near real time.

35. The system of claim 31, wherein the second voltage amplitude relates to one of a reduced and increased amplitude in relation to the first amplitude.

36. The system of claim 31, further comprising a digital-to-analog converter configured to convert the digital audio data to an analog audio signal and output the received analog audio signal characterized by a second voltage amplitude.

37. The system of claim 31, wherein the DSP is to detect the threshold voltage of the ADC related to at least one of a distortion threshold and clipping threshold.

38. The system of claim 31, wherein the DSP is to determine the first voltage amplitude of the analog audio signal based on the received digital audio data.

39. The system of claim 31, wherein the DSP is further configured to:
detect a distortion level of the received analog audio signal; and
adjust the gain control signal for the amplifier based, at least in part, on the detected distortion level.

40. The system of claim 31, wherein the amplifier is further configured to amplify the received analog audio signal by a gain of one based on the gain control signal received by the amplifier.
